(19) United States
(12) Patent Application Publication
(10) Pub. No.: US 2011/0058136 A1
(43) Pub. Date: Mar. 10, 2011

(54) LIQUID CRYSTAL DISPLAY STRUCTURE AND MANUFACTURING METHOD THEREOF

(75) Inventors: YUEH-PING CHANG, Miao-Li County (TW); CHAO-YI HUNG, Miao-Li County (TW)

(73) Assignee: CHIMEI INNOLUX CORPORATION, Miao-Li County (TW)

(21) Appl. No.: 12/850,613

(22) Filed: Aug. 4, 2010

(30) Foreign Application Priority Data
Sep. 4, 2009 (CN) 200910306588.2

(51) Int. Cl. G02F 1/1339; H01L 33/00

(52) U.S. Cl. 349/155; 438/34; 257/E33.053

(57) ABSTRACT

A liquid crystal display structure includes a top substrate, a bottom substrate, a gate metal layer, a pixel region, a main spacer, an auxiliary spacer and liquid crystal molecules. The gate metal layer and the pixel region are located between the top substrate and the bottom substrate, and are disposed on the bottom substrate. The bottom substrate overlaps with the gate metal layer. The pixel regions are adjacent to the gate layer metal but are separated from the gate metal layer. The main spacer and the auxiliary spacer are disposed on the top substrate. The main spacer extends downward to the gate metal layer, and the auxiliary spacer is located on the outside of the region which encompasses the gate metal layer, and does not overlap with the gate metal layer. The liquid crystal molecules are filled into the gap between the top substrate and the bottom substrate.

### BACKGROUND OF THE DISCLOSURE

1. Field of the Disclosure

The present disclosure relates to a liquid crystal display, and in particular relates to a liquid crystal display having spacers.

2. Description of the Related Art

A liquid crystal display (LCD) is one of the most common displays around. A liquid crystal display usually includes a top substrate and a bottom substrate. A color filter and a thin film transistor are disposed on the top substrate. Spacers are interposed between the two substrates such that the two substrates are spaced apart from each other by a distance for liquid crystal to be filled therein.

When fabricating a liquid crystal display panel, the periphery of a bottom substrate may be coated with sealant, while liquid crystal (LC) is dispersed on the substrate under a vacuum environment. The top substrate and the bottom substrate are aligned, and then the surrounding pressure is adjusted back to an atmospheric pressure to assembly the liquid crystal display panel, and spacers are utilized to support the two substrates. The amount of liquid crystal used is determined by the volume between the two substrates, and the height and width of the spacers. Therefore, before dispersing the liquid crystals, it is desirable to confirm the distance between the two substrates, and the height, width and amount of the spacers.

However, a bottleneck of the manufacturing process is to further increase operating margin of the liquid crystal display. Basically, under a low-temperature bubble test, there is room for only a small deviation in the amount of liquid crystal needed between two substrates. However, the low-temperature bubbles are formed, also refers to as vacuum voids, between two substrates, due to the liquid crystal shrinking under a low temperature. Specifically, the voids, leading to the formation of so-called vacuum bubbles, are formed when the volume between two substrates is larger than the amount of liquid crystal therein, which is resulted from inaccurate amount of the liquid crystal or shifted height of the spacers.

Therefore, a new liquid crystal display is desired, the distance between the substrates can be maintained, and voids resulting from vacuum bubbles can be avoided.

### BRIEF SUMMARY OF THE DISCLOSURE

According to one embodiment of the disclosure, a liquid crystal display includes a bottom substrate, a top substrate, a gate metal layer, a pixel region, a main spacer, an auxiliary spacer, and a plurality of liquid crystal molecules. The top substrate and the bottom substrate are aligned. The gate metal layer between the bottom substrate and the top substrate is disposed on the bottom substrate, and a portion of the bottom substrate overlaps with the gate metal layer. The pixel region located between the bottom substrate and the top substrate is disposed on the bottom substrate. The pixel region is adjacent to the gate metal layer and is separated from the gate metal layer. The main spacer and the auxiliary spacer extend from the top substrate toward the bottom substrate. The main spacer extends downward to the gate metal layer, and the auxiliary spacer is located on the outside of the region where the gate metal layer resides, so that the auxiliary spacer does not overlap with the gate metal layer. The liquid crystal molecules are filled into a gap between the bottom substrate and the top substrate.

According to another aspect of this disclosure, a method for manufacturing a liquid crystal display is provided. The liquid crystal display manufactured by the method has gaps with various heights, various volumes, and various areas to receive various sizes of spacers, such that external pressure can be equally distributed over the liquid crystal display at all positions therein to avoid degradation of image quality due to uneven pressure distribution within the display.

According to another embodiment of the disclosure, the method for manufacturing a liquid crystal display includes forming a gate metal layer on a bottom substrate such that a portion of the bottom substrate overlaps with the gate metal layer. A pixel region is formed on the bottom substrate. The pixel region is adjacent to the gate metal layer and is separated from the gate metal layer. Further, a plurality of main spacers and a plurality of auxiliary spacers are formed on a top substrate. The top substrate and the bottom substrate are assembled to each other, and the plurality of main spacers are aligned to the gate metal layer. The plurality of auxiliary spacers are located on an outside of the region where the gate metal layer resides, so that the plurality of auxiliary spacers does not overlap with the gate metal layer. Further, liquid crystal molecules may be filled into the gap between the bottom substrate and the top substrate.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1A is a schematic view showing a circuit layout of a liquid crystal display according to one embodiment of the disclosure.

FIG. 1B is a schematic view showing a cross-sectional view of a liquid crystal display according to one embodiment of the disclosure.

FIG. 1C is a schematic view showing a cross-sectional view of a liquid crystal display according to another embodiment of the disclosure.

FIG. 2 is schematic view showing a flow chat of manufacturing a liquid crystal display according to one embodiment of the disclosure.

### DETAILED DESCRIPTION OF THE DISCLOSURE

The following description is of the best-contemplated mode of carrying out the disclosure. This description is made for the purpose of illustrating the general principles of the disclosure and should not be taken in a limiting sense. The scope of the disclosure is best determined by reference to the appended claims.

In the following embodiments of a liquid crystal display and manufacturing method thereof, the distance between two substrates are maintained, so that voids resulting in vacuum bubbles between substrates may be avoided. Specifically, gaps with various heights, volumes, and area to receive various sizes of spacers can be adjusted so that liquid crystal molecules may be equally dispersed therein according to requirements. Accordingly, external pressure can be equally distributed over the liquid crystal molecules throughout the display at all positions therein to improve image quality.

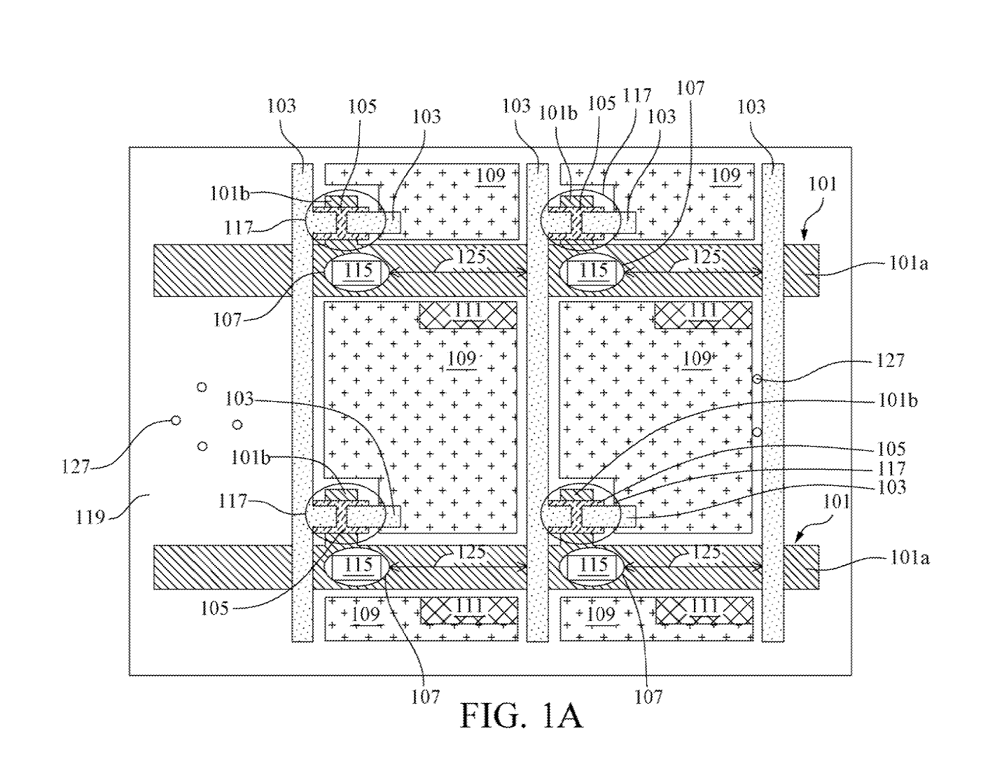

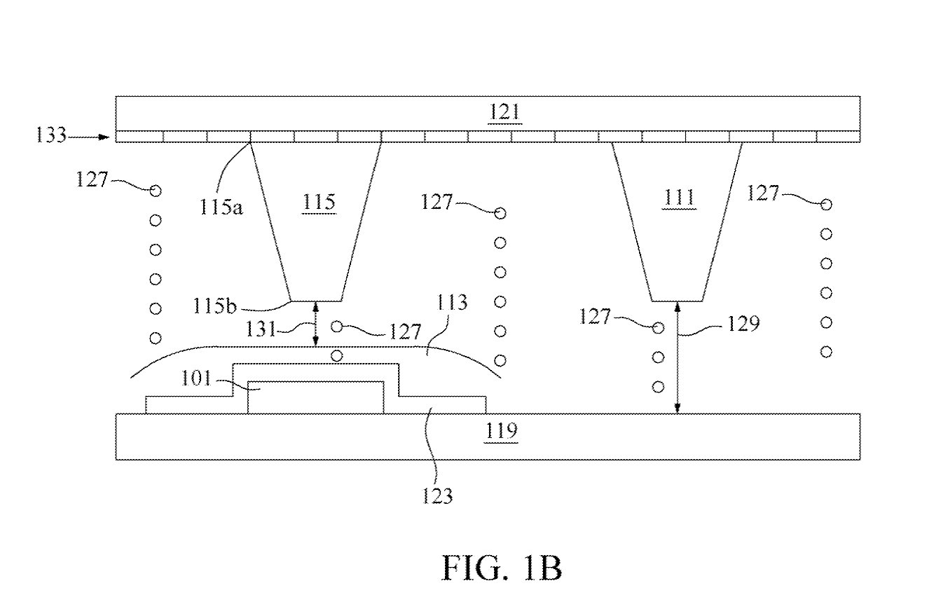

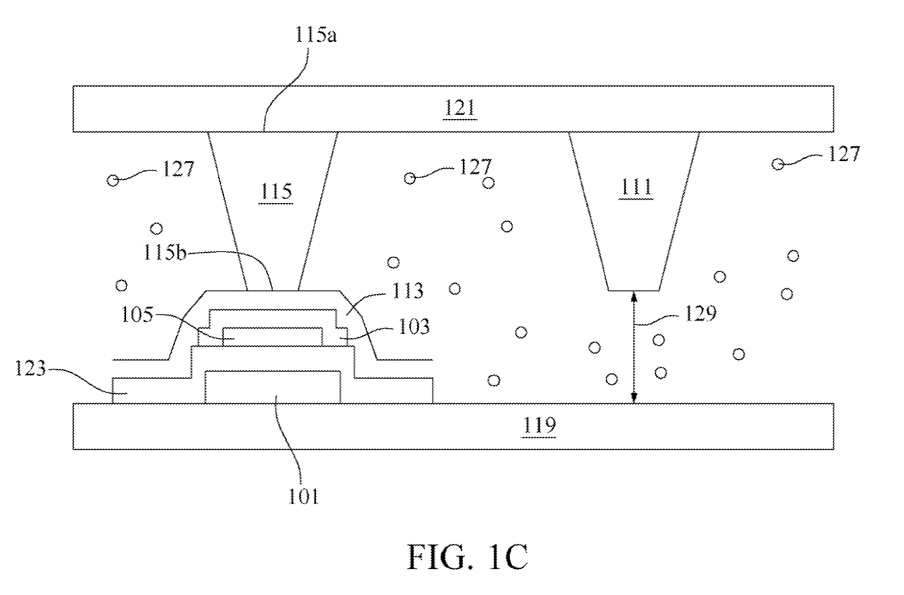

FIG. 1A to 1C are schematic views showing a circuit layout and cross-sectional views of a liquid crystal display according to an embodiment of the disclosure. The liquid crystal display includes a bottom substrate 119, a top substrate 121, a gate metal layer 101, a pixel region 109, a main spacer 115, an auxiliary spacer 111, and liquid crystal molecules 127. The top substrate 121 is disposed opposite to the bottom substrate 119. The gate metal layer 101 between the bottom substrate 119 and the top substrate 121 is disposed on the bottom substrate 119.

Referring to FIG. 1A, the gate metal layer 101 covers a portion of the bottom substrate 119. The gate metal layer 101 has a block region 101b and an elongated region 101a, and the elongated region 101a is coupled to the block region 101b. A thin film transistor structure 117 is disposed on a block region of the gate metal layer. The thin film transistor structure 117 serves as a switch to determine whether or not a voltage signal on a data line is to be transmitted to the pixel region 109. Furthermore, a voltage which comes from a common electrode and a pixel electrode is utilized to twist the liquid crystal molecules 127. The pixel region 109 between the bottom substrate 119 and the top substrate 121 is disposed on the bottom substrate 119. The pixel region 109 is adjacent to the gate metal layer 101, and is separated from the gate metal layer 101. The liquid crystal molecules 127 are filled into a gap between the bottom substrate 119 and the top substrate 121. In an embodiment, a semiconductor material layer 107 may be optionally disposed on the gate metal layer 101. The main spacer 115 is located above the elongated region 101a of the gate metal layer 101. The auxiliary spacer 111 is disposed on an edge of the pixel region 109, and the edge of the pixel region 109 is adjacent to the main spacer 115. However, the auxiliary spacer 111 may also be disposed on the outside of the regions of the gate metal layer 101. Since the auxiliary spacer 111 is repositioned to the outside of the region where the gate metal layer 101 resides, there is an added distance 125 to receive the main spacer 115. As a result, size and shape of the main spacer 115 may be adjusted more freely, and the gap between the two substrates can be tailored to flexibly meet specific needs.

As shown in FIG. 1B, a color filter layer 133 is disposed on the top substrate 121. The main spacer 115 extends from the top substrate 121 toward the bottom substrate to reach a position above the gate metal layer 101. Specifically, the main spacer 115 is located above the elongated region 101 of the gate metal layer 101 (FIG. 1A). The auxiliary spacer 111 is extended from the top substrate 121 toward the bottom substrate 119, and the auxiliary spacer 111 is located the outside of the region where the gate metal layer 101 resides and does not overlap with the gate metal layer 101. In addition to the gate metal layer 101, other semiconductor material layers, such as a gate insulating layer 123, a via hole layer 113, or the like, may also be disposed on the gate metal layer 101.

The liquid crystal molecules 127 are filled into a gap between the main spacer 115 and underlying structure. The liquid crystal molecules 127 may also be filled into a gap between the auxiliary spacer 111 and the bottom substrate 119, and be filled in other gaps between the top substrate 121 and the bottom substrate 119. The main spacer 115 and the auxiliary spacer 111 may be a photo spacer or a ball spacer, and the photo spacer includes a top portion 115a and a bottom portion 115b, with the top portion 115a larger than the bottom portion 115b.

The main spacer 115 is disposed above the gate metal 101, while the auxiliary spacer 111 is repositioned to the outside of the region where the gate metal layer 101 resides, and the auxiliary spacer 111 does not overlap with the gate metal layer 101. Since the gate metal layer 101 has a certain thickness, a distance 131 between the gate metal layer 101 and the main spacer 115 is less than a distance 129 between the bottom substrate 119 and the auxiliary spacer 111. A difference between the distance 129 and the distance 131 equals to a thickness of the gate metal layer 101. If the difference between the distance 129 and the distance 131 is required to be increased, other semiconductor material layers, such as a gate insulating layer 123, a via hole layer 113, or the like, may be disposed on the gate metal layer 101.

Furthermore, as shown in FIG. 1C, the gate insulating layer 123, an amorphous silicon layer 105, a source/drain metal layer 103, and the via hole layer 113 are stacked on the gate metal layer 101 in sequence. That is, the difference between the distance below the main spacer 115 and the distance below the auxiliary spacer 111 may vary by the number of semiconductor layers below the main spacer 115.

Specifically, when only the gate insulating layer 123 is disposed on the gate metal layer 101, a sum of the thicknesses of the gate insulating material 123 and the gate metal layer 101 equals to the difference between the two distances, distance 129 and 131. If the amorphous silicon layer 105 is further stacked on the gate insulating layer 123, a sum of the thicknesses of the amorphous silicon layer 105, the gate insulating layer 123, and the gate metal layer 101 equals to the difference between the two distances, distance 129 and 131. The source/drain metal layer 103 may further be stacked on the amorphous silicon layer 105, and a sum of the thicknesses of the source/drain metal layer 103, the amorphous silicon layer 105, the gate insulating layer 123, and the gate metal layer 101, equals to a difference between the two distances, distance 129 and 131. Finally, the via hole layer 113 may be stacked on the source/drain metal layer 103 such that the main spacer 115 contacts a top of the via hole layer 113, and the distance between the main spacer 115 and the underlying structure is zero.

As a result, gaps with various heights, volumes, and area to receive various sizes of spacers can be adjusted depending for particular requirements, so that liquid crystal molecules may be equally dispersed therein and voids which lead to vacuum bubbles between the two substrates may be avoided. Moreover, external pressure can be equally distributed over the liquid crystal molecules throughout the display at all positions therein to improve image quality. Furthermore, since the material of the semiconductor material described above is the same as the thin film transistor of the liquid crystal display, the semiconductor material may be formed when manufacturing the thin film transistor to adjust the volume of the gaps below the main spacer and the auxiliary spacer. No additional processing steps is required, and the fabrication process is simplified.

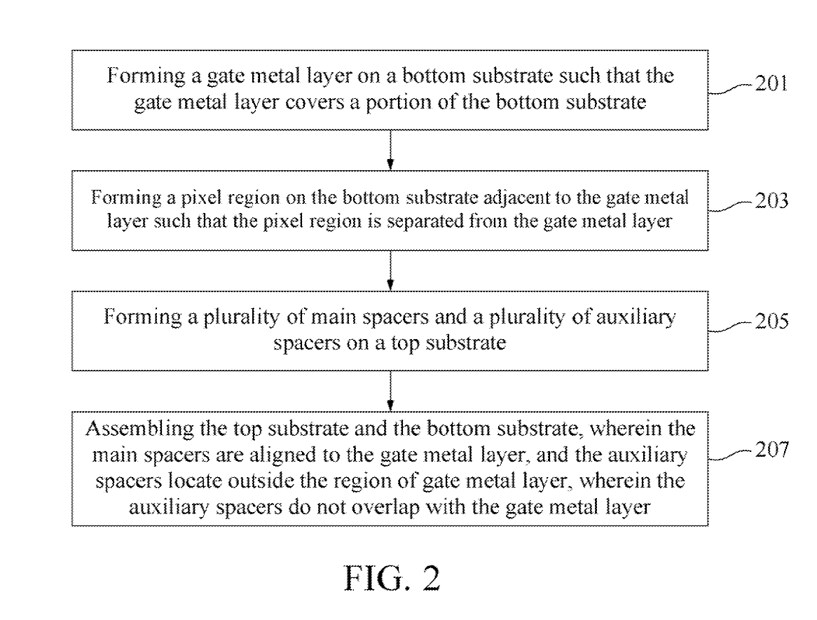

FIG. 2 is a flow chart for manufacturing a liquid crystal display according to one embodiment of the disclosure. In the manufacturing method, first, a gate metal layer is formed on a bottom substrate such that the gate metal layer covers a portion of the bottom substrate (step 201). In addition to the gate metal layer, a gate insulating layer, an amorphous silicon layer, a source/drain metal layer, and a via hole layer may be stacked on the gate metal layer in sequence, to adjust a length, a thickness, an area, and a volume of a gap below the main spacer. Next, a pixel region is formed on the bottom substrate and a region where the pixel is formed is adjacent to the gate metal layer such that the pixel region is separated from the gate metal layer (step 203).

After step 203, a main spacer and an auxiliary spacer may be formed on a top substrate (step 205). Then, the top substrate and the bottom substrate are assembled. The main spacer is aligned to the gate metal layer, and the auxiliary spacer is located on an outside of the region where the gate metal layer resides, and the auxiliary spacer dose not overlap with the gate metal layer (step 207). Additionally, the top portions of the main spacer and the auxiliary spacer may be attached to the top substrate, and the auxiliary spacer is disposed on an edge of the pixel region. The bottom portions of the main spacer and the auxiliary spacer face toward the bottom substrate, and the top portions of the main spacer and the auxiliary spacer are larger than the bottom portions of the main spacer and the auxiliary spacer respectively. In step 201 or step 207, the liquid crystal molecules may be filled into the gaps between the top substrate and the bottom substrate.

In conclusion, in the embodiments of the disclosure, an auxiliary spacer of a liquid crystal display is removed from a region where a gate metal layer resides, so that the auxiliary spacer does not overlap with the gate metal layer. The additional space may be utilized to receive a main spacer after the auxiliary spacer is removed, and therefore design flexibility of the size and shape of the main spacer may be increased. In addition, for the liquid crystal display in the embodiments, length, height, areas, or volume of gaps or distances below the main spacer and the auxiliary spacer may be adjusted. As a result, liquid crystal molecules can be equally and fully dispersed in the gaps to avoid the formation of vacuum bubbles between the two substrates. Meanwhile, external pressure can be equally distributed over the liquid crystal molecules throughout the display at all positions therein to improve image quality.

Additionally, the material of the semiconductor material layers described above is the same as the material of the thin film transistor of the liquid crystal display. Therefore, during the process for manufacturing the thin film transistor, the semiconductor material may be formed to adjust the volume of the gaps below the main spacer and the auxiliary spacer, so that no additional processing steps is required, and the fabrication process is simplified.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A liquid crystal display, comprising:
a bottom substrate;
a top substrate disposed opposite to the bottom substrate;
a gate metal layer between the bottom substrate and the top substrate and disposed on the bottom substrate, wherein the gate metal layer covers a portion of the bottom substrate;
a pixel region between the bottom substrate and the top substrate and disposed on the bottom substrate, wherein the pixel region is adjacent to the gate metal layer, and separated from the gate metal layer;
a main spacer extending from the top substrate toward the bottom substrate to above the gate metal layer;
an auxiliary spacer extending from the top substrate toward the bottom substrate, wherein the auxiliary spacer is located on an of a region where the gate metal layer resides and does not overlap with the gate metal layer; and
a plurality of liquid crystal molecules filling in a gap between the bottom substrate and the top substrate.

2. The liquid crystal display as claimed in claim 1, wherein the gate metal layer comprises: a block region and an elongated region coupled to the block region having the main spacer disposed thereon.

3. The liquid crystal display as claimed in claim 2, further comprising a thin film transistor structure disposed on the block region of the gate metal layer, wherein the thin film transistor structure determines whether or not a voltage signal on a data line is to be transmitted to the pixel region to twist the plurality of liquid crystal molecules.

4. The liquid crystal display as claimed in claim 1, wherein the auxiliary spacer is disposed on an edge of the pixel region, wherein the edge is adjacent to the main spacer.

5. The liquid crystal display as claimed in claim 1, wherein a distance between the gate metal layer and the main spacer is less than a distance between the bottom substrate and the auxiliary substrate, and a thickness of the gate metal layer equals to a difference between the two distances.

6. The liquid crystal display as claimed in claim 5, further comprising a gate insulating layer stacked on the gate metal layer such that a distance between the gate insulating layer and the main spacer is less than a distance between the bottom substrate and the auxiliary spacer, and a sum of the thicknesses of the gate insulating layer and the gate metal layer equals to a difference between the two distances.

7. The liquid crystal display as claimed in claim 6, further comprising an amorphous silicon layer stacked on the gate insulating layer such that a distance between the amorphous silicon layer and the main spacer is less than a distance between the bottom substrate and the auxiliary spacer, and a sum of the thicknesses of the amorphous silicon layer, the gate insulating layer, and the gate metal layer equals to a difference between the two distances.

8. The liquid crystal display as claimed in claim 7, further comprising a source/drain metal layer stacked on the amorphous silicon layer such that a distance between the source/drain metal layer and the main spacer is less than a distance between the bottom substrate and the auxiliary spacer, and a sum of the thicknesses of the source/drain metal layer, the amorphous silicon layer, the gate insulating layer, and the gate metal layer equals to a difference between the two distances.

9. The liquid crystal display as claimed in claim 8, further comprising a via hole layer stacked on the source/drain metal layer such that a distance between the via hole layer and the main spacer is less than a distance between the bottom substrate and the auxiliary spacer, and a sum of the thicknesses of the via hole layer, the source/drain metal layer, the amorphous silicon layer, the gate insulating layer, and the gate metal layer equals to a difference between the two distances.

10. The liquid crystal display as claimed in claim 9, wherein the main spacer extending from the top substrate contacts a top of the gate metal layer.

11. The liquid crystal display as claimed in claim 1, wherein both of the main spacer and the auxiliary spacer are photo spacers.

12. The liquid crystal display as claimed in claim 11, wherein the photo spacer includes a bottom portion and a top portion, wherein the top portion in contact with the top substrate is larger than the bottom portion.

13. The liquid crystal display as claimed in claim 1, further comprising a color filter layer disposed on the top substrate.

14. A method for manufacturing a liquid crystal display, comprising:
forming a gate metal layer on a bottom substrate such that the gate metal layer covers a portion of the bottom substrate;
forming a plurality of main spacers and a plurality of auxiliary spacers on a top substrate; and
assembling the top substrate and the bottom substrate such that the main spacers are aligned to the gate metal layer, and the auxiliary spacers are located on an outside of a region where the gate metal layer resides so that the auxiliary spacers do not overlap with the gate metal layer.

15. The method for manufacturing a liquid crystal display as claimed in claim 14, further comprising forming a plurality of pixel regions on the bottom substrate such that the plurality of pixel regions is separated from the gate metal layer.

16. The method for manufacturing a liquid crystal display as claimed in claim 14, further comprising attaching top portions of the main spacers and the auxiliary spacers with the top substrate such that bottom portions of the main spacers and the auxiliary spacers face the bottom substrate, wherein the top portions of the main spacers and the auxiliary spacers are larger than the bottom portions of the main spacers and the auxiliary spacers respectively.

17. The method for manufacturing a liquid crystal display as claimed in claim 14, further comprising stacking a gate insulating layer on the gate metal layer such that a distance between the gate insulating layer and the main spacer is less than a distance between the bottom substrate and the auxiliary spacer, wherein a sum of the thicknesses of the gate insulating layer and the gate metal layer equals to a difference between the two distances.

18. The method for manufacturing a liquid crystal display as claimed in claim 17, further comprising stacking an amorphous silicon layer on the gate insulating layer such that a distance between the amorphous silicon layer and the main spacer is less than a distance between the bottom substrate and the auxiliary spacer.

19. The method for manufacturing a liquid crystal display as claimed in claim 18, further comprising stacking a source/drain metal layer on the amorphous silicon layer such that a distance between the source/drain metal layer and the main spacer is less than a distance between the bottom substrate and the auxiliary spacer.

20. The method for manufacturing a liquid crystal display as claimed in claim 19, further comprising stacking a via hole layer on the source/drain metal layer such that a distance between the via hole layer and the main spacer is less than a distance between the bottom substrate and the auxiliary spacer.
